(19) United States
(12) Patent Application Publication
(10) Pub. No.: US 2022/0377925 A1
(43) Pub. Date: Nov. 24, 2022

(54) SERVER AND ELECTRONIC ASSEMBLY

(71) Applicants: Inventec (Pudong) Technology Corporation, Shanghai (CN); INVENTEC CORPORATION, Taipei (TW)

(72) Inventors: Wei Wang, Shanghai (CN); Guang-Zhao TIAN, Shanghai (CN)

(21) Appl. No.: 17/381,707

(22) Filed: Jul. 21, 2021

(30) Foreign Application Priority Data
May 24, 2021 (CN) 202110565513.7

(51) Int. Cl. H05K 7/14; G06F 1/18

(52) U.S. Cl. CPC H05K 7/1487; G06F 1/184; G06F 1/185

(57) ABSTRACT

A server and an electronic assembly including riser card and expansion card. Riser card includes first circuit board, first connector, second connector, and fastening pillar. First connector and second connector are fixed on and electrically connected to first circuit board. Fastening pillar is fixed on first circuit board. Expansion card includes second circuit board, third connector, and fastener. Third connector is fixed on and electrically connected to second circuit board. Third connector is plugged into second connector. Fastener penetrates through second circuit board and is fixed on fastening pillar of riser card so as to fix first circuit board and second circuit board to each other. Specification of first connector of riser card is different from specification of second connector of riser card.

### CROSS-REFERENCE TO RELATED APPLICATIONS

This non-provisional application claims priority under 35 U.S.C. § 119(a) on Patent Application No(s). 202110565513.7 filed in China, on May 24, 2021, the entire contents of which are hereby incorporated by reference.

### BACKGROUND OF THE INVENTION

### Technical Field of the Invention

The invention relates to a server and an electronic assembly, more particularly to a server and an electronic assembly including an expansion card.

### Description of the Related Art

With the development of the data science, the demand of the performance of data center is enhanced. Manufactures have developed several new techniques about server and network interface card to suit the requirements for transferring and processing lots of data. The network interface card meeting the Open Compute Project (OCP) is one of the new techniques that has been developed. Specifically, OPC 2.0 specification has been developed into OCP 3.0 specification, and connectors meeting OCP 3.0 specification are currently used in most of the servers.

However, the network interface card meeting OPC 2.0 specification is unable to installed in most of the servers using connectors meeting OCP 3.0 specification. Thus, a large inventory of the network interface card meeting OPC 2.0 specification are left.

### SUMMARY OF THE INVENTION

The invention is to provide a server and an electronic assembly allowing the network interface card of old specification to be installed in the server using the connectors of new specification.

One embodiment of this invention provides a server including a chassis, a motherboard and an electronic assembly. The motherboard includes a main circuit board, a first connector, and two slide rails. The first connector is fixed on and electrically connected to the main circuit board. The two slide rails are fixed to the main circuit board and spaced apart from each other. The main circuit board is fixed to the chassis. The electronic assembly includes a riser card and an expansion card. The riser card includes a first circuit board, a second connector, a third connector, and a fastening pillar. The second connector and the third connector are fixed on and electrically connected to the first circuit board. The second connector is plugged into the first connector of the motherboard. The fastening pillar is fixed on the first circuit board. The first circuit board is disposed in the two slide rails. The expansion card includes a second circuit board, a fourth connector, and a first fastener. The fourth connector is fixed on and electrically connected to the second circuit board. The fourth connector is plugged into the third connector. The first fastener penetrates through the second circuit board and is fixed on the fastening pillar of the riser card so as to fix the first circuit board and the second circuit board to each other. A specification of the second connector of the riser card is different from a specification of the third connector of the riser card.

Another embodiment of this invention provides an electronic assembly including a riser card and an expansion card. The riser card includes a first circuit board, a first connector, a second connector, and a fastening pillar. The first connector and the second connector are fixed on and electrically connected to the first circuit board. The fastening pillar is fixed on the first circuit board. The expansion card includes a second circuit board, a third connector, and a fastener. The third connector is fixed on and electrically connected to the second circuit board. The third connector is plugged into the second connector. The fastener penetrates through the second circuit board and is fixed on the fastening pillar of the riser card so as to fix the first circuit board and the second circuit board to each other. A specification of the first connector of the riser card is different from a specification of the second connector of the riser card.

According to the server and the electronic assembly disclosed by above embodiments, the specification of the first connector of the riser card is different from the specification of the second connector of the riser card. In other words, the riser card includes two connectors with different specifications, and one connector is suitable for the old specification and the other connector is suitable for the new specification. Thus, the expansion card of old specification is allowed to be electrically connected to the first connector of the new specification of the main circuit board via the riser card. Therefore, the expansion card of old specification can be installed in the server using connectors of new specification, such that the inventories of the expansion card of old specification can be decreased. In addition, the electronic assembly can be installed in the chassis of the server in a convenient and tool-less manner.

### BRIEF DESCRIPTION OF THE DRAWINGS

The present invention will become more fully understood from the detailed description given hereinbelow and the accompanying drawings which are given by way of illustration only and thus are not limitative of the present invention and wherein:

FIG. 1 is a partially enlarged perspective view of a server according to one embodiment of the invention; and

FIG. 2 is a partially enlarged exploded view of the server in FIG. 1.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

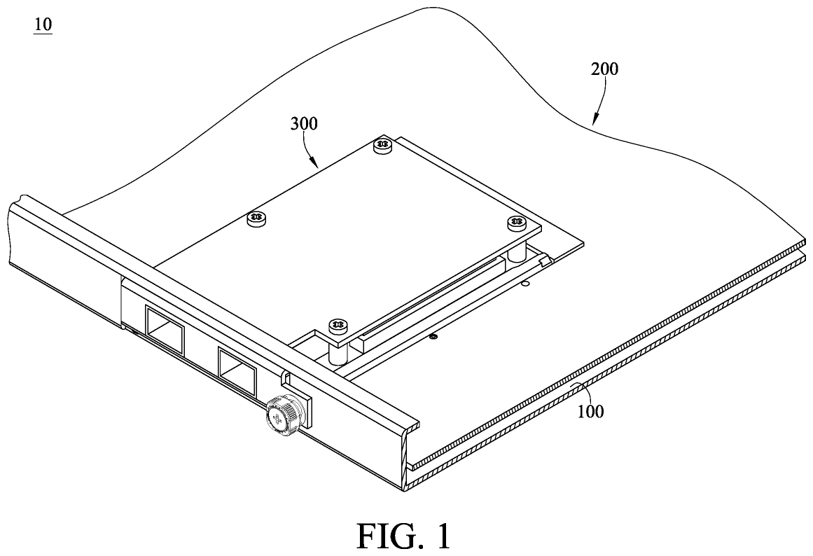

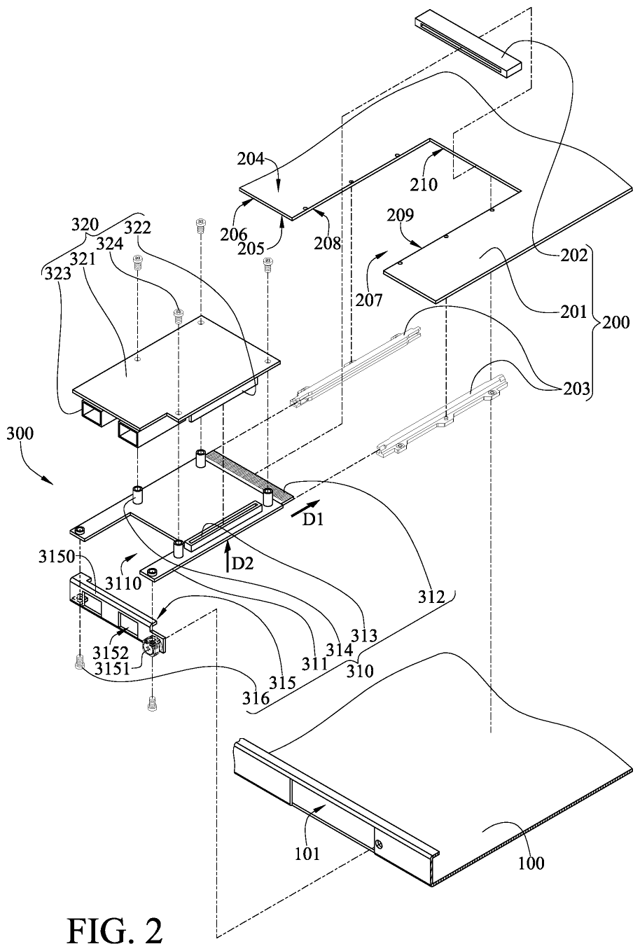

Please refer to FIGS. 1 and 2. FIG. 1 is a partially enlarged perspective view of a server 10 according to one embodiment of the invention. FIG. 2 is a partially enlarged exploded view of the server 10 in FIG. 1.

In this embodiment, the server 10 includes a chassis 100, a motherboard 200 and an electronic assembly 300. In this embodiment, the chassis 100 has an opening 101.

The motherboard 200 includes a main circuit board 201, a first connector 202 and two slide rails 203. In this embodiment, the main circuit board 201 is fixed to the chassis 100 and has a top surface 204, a bottom surface 205, a side surface 206, a mounting recess 207, a first inner surface 208, a second inner surface 209 and a third inner surface 210. The top surface 204 faces away from the bottom surface 205. The side surface 206 connects the top surface 204 and the bottom surface 205. The mounting recess 207 penetrates through the top surface 204 and the bottom surface 205 and recesses inward from the side surface 206. The first inner surface 208 faces toward the second inner surface 209. The third inner surface 210 connects the first inner surface 208 and the second inner surface 209. The mounting recess 207 is formed by the first inner surface 208, the second inner surface 209 and the third inner surface 210. The first connector 202 is fixed to the third inner surface 210 of the main circuit board 201 and is electrically connected to the main circuit board 201. The two slide rails 203 are respectively fixed to the first inner surface 208 and the second inner surface 209 of the main circuit board 201 so as to be spaced apart from each other.

In other embodiments, the main circuit board may not have the mounting recess 207. In such embodiments, the first connector and the slide rails may be disposed on the top surface of the main circuit board.

The electronic assembly 300 includes a riser card 310 and an expansion card 320. In this embodiment, the riser card 310 includes a first circuit board 311, a second connector 312, a third connector 313, a plurality of fastening pillars 314, a front window 315 and a plurality of fasteners 316.

In this embodiment, the first circuit board 311 is located in the mounting recess 207 of the main circuit board 201 and disposed in the two slide rails 203. The second connector 312 and the third connector 313 are fixed on and electrically connected to the first circuit board 311. The second connector 312 protrudes from the first circuit board 311 along a first protruding direction D1. The third connector 313 protrudes from the first circuit board 311 along a second protruding direction D2. In this embodiment, the first protruding direction D1 is perpendicular to the second protruding direction D2. The specification of the second connector 312 of the riser card 310 is different from the specification of the third connector 313 of the riser card 310. For example, the specification of the second connector 312 meets the OCP 3.0 specification (the new specification), and the specification of the third connector 313 meets the OCP 2.0 specification (the old specification). The first circuit board 311 has a recess 3110. The recess 3110 of the first circuit board 311 is recessed from a side of the first circuit board 311 that is located away from the second connector 312. The second connector 312 is plugged into the first connector 202 of the motherboard 200. The fastening pillars 314 are fixed on and protrude from the first circuit board 311. In this embodiment, the front window 315 includes a window body 3150 and a thumb screw 3151. In this embodiment, the window body 3150 has two through holes 3152. The fasteners 316 are, for example, screws. The window body 3150 is fixed to a side of the first circuit board 311 that is located away from the second connector 312 via the fasteners 316, and is located in the opening 101 of the chassis 100. In addition, the window body 3150 is fixed to the chassis 100 via the thumb screw 3151.

In other embodiments, the first circuit board may not have the recess 3110. In other embodiments, the first protruding direction of the second connector may be parallel to or be at an acute angle to the second protruding direction of the third connector. In other embodiments, the front window may not include the thumb screw 3151 and the window body may be adhered to the chassis. In other embodiments, the riser card may not include the fasteners 316, and the front window may be adhered to the first circuit board. In other embodiments, the chassis may not have the opening 101 and the riser card may not include the front window 315. In such embodiments, the riser card may be installed in the slide rails without being directly fixed to the chassis.

In this embodiment, the expansion card 320 includes a second circuit board 321, a fourth connector 322, two ports 323 and a plurality of fasteners 324. In this embodiment, the expansion card 320 is, for example, a 1 G, 10 G or 25 G network interface card of OCP 2.0 specification. The fourth connector 322 is fixed on and electrically connected to the second circuit board 321. The fourth connector 322 is plugged into the third connector 313. The two ports 323 are fixed on the second circuit board 321 and are disposed through the two through holes 3152 of the window body 3150, respectively. The fasteners 324 penetrate through the second circuit board 321 and are respectively fixed on the fastening pillars 314 of the riser card 310 so as to fix the first circuit board 311 and second circuit board 321 to each other.

In other embodiments, the expansion card may be a graphic card or any other suitable type of cards. In such embodiments, the expansion card may not include the ports 323 and the window body may not have the through holes 3152.

According to the server and the electronic assembly disclosed by above embodiments, the specification of the first connector of the riser card is different from the specification of the second connector of the riser card. In other words, the riser card includes two connectors with different specifications, and one connector is suitable for the old specification and the other connector is suitable for the new specification. Thus, the expansion card of old specification is allowed to be electrically connected to the first connector of the new specification of the main circuit board via the riser card. Therefore, the expansion card of old specification can be installed in the server using connectors of new specification, such that the inventories of the expansion card of old specification can be decreased. In addition, the electronic assembly can be installed in the chassis of the server in a convenient and tool-less manner.

It will be apparent to those skilled in the art that various modifications and variations can be made to the present invention. It is intended that the specification and examples be considered as exemplary embodiments only, with a scope of the invention being indicated by the following claims and their equivalents.

What is claimed is:

1. A server, comprising:
a chassis;
a motherboard, comprising a main circuit board, a first connector, and two slide rails, wherein the first connector is fixed on and electrically connected to the main circuit board, the two slide rails are fixed to the main circuit board and spaced apart from each other, the main circuit board is fixed to the chassis; and
an electronic assembly, comprising:
a riser card, comprising a first circuit board, a second connector, a third connector, and a fastening pillar, wherein the second connector and the third connector are fixed on and electrically connected to the first circuit board, the second connector is plugged into the first connector of the motherboard, the fastening pillar is fixed on the first circuit board, and the first circuit board is disposed in the two slide rails; and
an expansion card, comprising a second circuit board, a fourth connector, and a first fastener, wherein the fourth connector is fixed on and electrically connected to the second circuit board, the fourth connector is plugged into the third connector, the first fastener penetrates through the second circuit board and is fixed on the fastening pillar of the riser card so as to fix the first circuit board and the second circuit board to each other;
wherein a specification of the second connector of the riser card is different from a specification of the third connector of the riser card.

2. The server according to claim 1, wherein the first circuit board has a recess recessed from a side of the first circuit board that is located away from the second connector.

3. The server according to claim 1, wherein the second connector protrudes from the first circuit board along a first protruding direction, the third connector protrudes from the first circuit board along a second protruding direction, and the first protruding direction is perpendicular to the second protruding direction.

4. The server according to claim 1, wherein the main circuit board of the motherboard has a top surface, a bottom surface, a side surface, a mounting recess, a first inner surface, a second inner surface, and a third inner surface, the top surface faces away from the bottom surface, the side surface connects the top surface and the bottom surface, the mounting recess penetrates through the top surface and the bottom surface and recessed from the side surface, the first inner surface faces toward the second inner surface, the third inner surface connects the first inner surface and the second inner surface, the mounting recess is formed by the first inner surface, the second inner surface and the third inner surface, the first connector is fixed to the third inner surface, the two slide rails are respectively fixed to the first inner surface and the second inner surface, and the first circuit board is located in the mounting recess.

5. The server according to claim 1, wherein the chassis has an opening, the riser card further comprises a front window, the front window is fixed to a side of the first circuit board that is located away from the second connector, the front window is fixed to the chassis and is located in the opening.

6. The server according to claim 5, wherein the riser card further comprises a second fastener, the front window and the first circuit board are fixed to each other via the second fastener.

7. The server according to claim 5, wherein the front window comprises a window body and a thumb screw, the window body is fixed to the first circuit board and located in the opening, the window body is fixed to the chassis via the thumb screw.

8. The server according to claim 5, wherein the expansion card is a network interface card, the expansion card further comprises two ports, the front window has two through holes, the two ports are fixed on the second circuit board and are respectively disposed through the two through holes.

9. An electronic assembly, comprising:
a riser card, comprising a first circuit board, a first connector, a second connector, and a fastening pillar, wherein the first connector and the second connector are fixed on and electrically connected to the first circuit board, the fastening pillar is fixed on the first circuit board; and
an expansion card, comprising a second circuit board, a third connector, and a fastener, wherein the third connector is fixed on and electrically connected to the second circuit board, the third connector is plugged into the second connector, the fastener penetrates through the second circuit board and is fixed on the fastening pillar of the riser card so as to fix the first circuit board and the second circuit board to each other;
wherein a specification of the first connector of the riser card is different from a specification of the second connector of the riser card.

10. The server according to claim 9, wherein the first circuit board has a recess recessed from a side of the first circuit board that is located away from the first connector.
